(19) United States
(12) Patent Application Publication
(10) Pub. No.: US 2021/0226178 A1
(43) Pub. Date: Jul. 22, 2021

(54) ORGANIC ELECTROLUMINESCENCE DISPLAY PANEL, MANUFACTURING METHOD THEREOF AND DISPLAY DEVICE

(71) Applicants: BOE TECHNOLOGY GROUP CO., LTD., Beijing (CN); ORDOS YUANSHENG OPTOELECTRONICS CO., LTD., Ordos, Inner Mongolia (CN)

(72) Inventor: Haotian WANG, Beijing (CN)

(21) Appl. No.: 16/300,413

(22) PCT Filed: Apr. 2, 2018
(86) PCT No.: PCT/CN2018/081604

§ 371 Date: Nov. 9, 2018

(30) Foreign Application Priority Data
May 12, 2017 (CN) 201710333397.X

(51) Int. Cl. H01L 51/56; H01L 51/52

(52) U.S. Cl. CPC H01L 51/56; H01L 51/5253; H01L 51/5246

(57) ABSTRACT

An organic electroluminescence display panel, a manufacturing method thereof and a display device are provided. The manufacturing method includes: forming an organic electroluminescent display component on a base substrate; providing an encapsulation cover; forming a high-temperature resistant film on at least a partial region of a surface of the organic electroluminescent display component and/or a surface of the encapsulation cover with the at least a partial region corresponding to pixels at an outermost edge of the organic electroluminescent display component; forming a frit on the encapsulation cover or the base substrate to surround a region of the encapsulation cover or the base substrate corresponding to the pixels at the outermost edge of the organic electroluminescent display component; assembling the encapsulation cover with the organic electroluminescent display component, and sintering a region of the encapsulation cover corresponding to a region of the frit with laser.

### TECHNICAL FIELD

The present disclosure relates to an organic electroluminescence display panel, a manufacturing method thereof, and a display device.

### BACKGROUND

Organic light-emitting diode (OLED) device is a display illumination technology which has been progressively developed in recent years. OLED device is considered to have broad application prospects for its advantages such as high response, high contrast, and flexibility. However, OLED device is easily corroded by moisture and oxygen, which may cause damage thereto. Therefore, the selection of a better encapsulation way is especially important for the OLED device.

### SUMMARY

Embodiments of the present disclosure provide a manufacturing method of an organic electroluminescent display panel, including: forming an organic electroluminescent display component on a base substrate; providing an encapsulation cover; forming a high-temperature resistant film on at least a partial region of at least one of a surface of the organic electroluminescent display component and a surface of the encapsulation cover with the at least a partial region corresponding to pixels at an outermost edge of the organic electroluminescent display component; forming a frit on the encapsulation cover or the base substrate with the frit surrounding a region of the encapsulation cover or the base substrate corresponding to the pixels at the outermost edge of the organic electroluminescent display component; assembling the encapsulation cover with the organic electroluminescent display component to form a cell, and sintering a region of the encapsulation cover corresponding to a region where the frit is located by using a laser.

According to an embodiment of the present disclosure, for example, the high-temperature resistant film is formed on the surface of the encapsulation cover; forming a frit on the encapsulation cover or the base substrate with the frit surrounding a region of the encapsulation cover or the base substrate corresponding to the pixels at the outermost edge of the organic electroluminescent display component includes: forming the frit on the encapsulation cover, at a side of the encapsulation cover where the high-temperature resistant film is located.

According to an embodiment of the present disclosure, for example, the high-temperature resistant film is formed on the surface of the encapsulation cover; forming a frit on the encapsulation cover or the base substrate with the frit surrounding a region of the encapsulation cover or the base substrate corresponding to the pixels at the outermost edge of the organic electroluminescent display component includes: forming the frit on the encapsulation cover, at a side of the encapsulation cover facing away from the high-temperature resistant film.

According to an embodiment of the present disclosure, for example, after sintering the region of the encapsulation cover corresponding to the region where the frit is located by using a laser, the method further includes removing the high-temperature resistant film.

According to an embodiment of the present disclosure, for example, the high-temperature resistant film is a transparent high-temperature resistant film.

According to an embodiment of the present disclosure, for example, the high-temperature resistant film is formed on the surface of the organic electroluminescent display component; forming a high-temperature resistant film on at least a partial region of at least one of a surface of the organic electroluminescent display component and a surface of the encapsulation cover with the at least a partial region corresponding to pixels at an outermost edge of the organic electroluminescent display component includes: forming a transparent high-temperature resistant film on the region corresponding to the pixels at the outermost edge of the organic electroluminescent display component.

According to an embodiment of the present disclosure, for example, forming a high-temperature resistant film on at least a partial region of at least one of a surface of the organic electroluminescent display component and a surface of the encapsulation cover includes: forming the high-temperature resistant film on a region corresponding to pixels in a first layer to a third layer at the outermost edge of the organic electroluminescent display component.

According to an embodiment of the present disclosure, for example, forming a high-temperature resistant film on at least a partial region of at least one of a surface of the organic electroluminescent display component and a surface of the encapsulation cover includes: forming the high-temperature resistant film on a region corresponding to all pixels of the organic electroluminescent display component.

According to an embodiment of the present disclosure, for example, the high-temperature resistant film is made of polyethylene terephthalate or polyimide.

According to an embodiment of the present disclosure, for example, the high-temperature resistant film has a thickness ranging from 100 Å to 500 Å.

Embodiments of the present disclosure provide an organic electroluminescence display panel manufactured by the manufacturing method as described above.

Embodiments of the present disclosure provide a display device including the organic electroluminescent display panel as described above.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the present disclosure.

FIG. 1 is a flowchart of a manufacturing method of an organic electroluminescence display panel provided by an embodiment of the present disclosure;

FIGS. 2a and 2b are top views of the organic electroluminescent display panel at a side where an encapsulation cover is located, in an embodiment of the present disclosure;

FIGS. 3a, 3b and 3c are schematic cross-sectional views of a high-temperature resistant film located at different positions taken along line AX in FIG. 2a;

FIGS. 4a, 4b and 4c are schematic cross-sectional views of the high-temperature resistant film located at different positions taken along line BB′ in FIG. 2b.

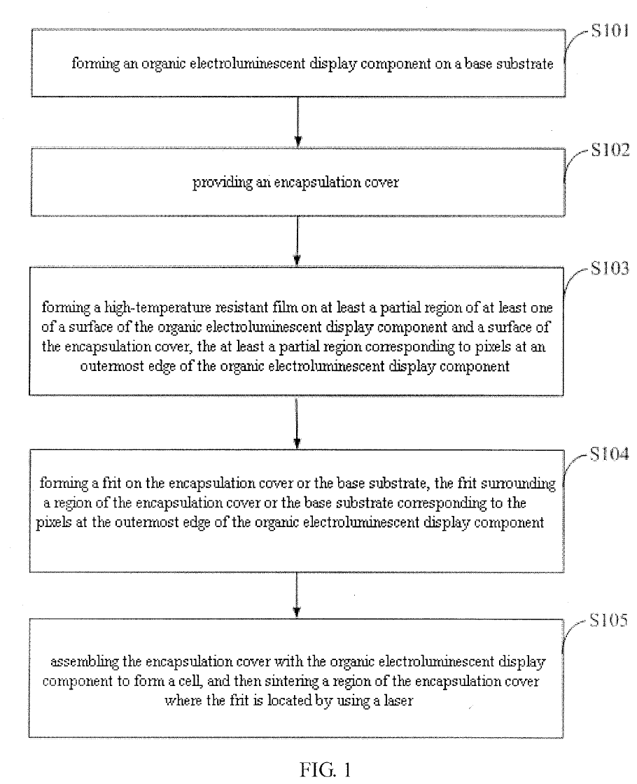

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

The OLED device is usually encapsulated in various ways. One of the methods is: bonding a base substrate with an encapsulation cover by a frit which is fused there-between, so as to protect the device against moisture and oxygen. However, in the manufacturing process, the frit is required to be sintered with a laser. Because the laser with higher energy may generate a higher temperature during the sintering process, pixel dots at an edge of a pixel area is easily burned and hence damaged, causing the display device to be blacken at a lower corner in a lighting state, which affects a display performance of the display device.

Therefore, how to prevent the pixel from being burned and damaged during the laser sintering process of the frit is a technical problem urgent to be solved.

To solve the problems that pixel dots are easily burned and damaged during the laser sintering process of the frit to affect the display performance of the display device, embodiments of the present disclosure provide an organic electroluminescence display panel, a manufacturing method thereof, and a display device.

Specific embodiments of the organic electroluminescent display panel, the manufacturing method thereof and the display device provided by the embodiments of the present disclosure are described in detail below with reference to the accompanying drawings. Thickness and shape of each film layer in the drawings do not reflect the true scale, and are merely intended to illustrate the present disclosure.

Embodiments of the present disclosure provide a manufacturing method of an organic electroluminescence display panel, including:

S101, forming an organic electroluminescent display component on a base substrate;

S102, providing an encapsulation cover;

S103, forming a high-temperature resistant film on at least a partial region of at least one of a surface of the organic electroluminescent display component and a surface of the encapsulation cover, the at least a partial region corresponding to pixels at an outermost edge of the organic electroluminescent display component;

S104, forming a frit on the encapsulation cover or the base substrate, the frit surrounding a region of the encapsulation cover or the base substrate corresponding to the pixels at the outermost edge of the organic electroluminescent display component; and

S105, assembling the encapsulation cover with the organic electroluminescent display component to form a cell, and then sintering a region of the encapsulation cover where the frit is located by using a laser.

In the above-described manufacturing method of the organic electroluminescent display panel provided by the embodiments of the present disclosure, the high-temperature resistant film is formed on at least one of the surface of the organic electroluminescent display component and the surface of the encapsulation cover, in a region corresponding to the pixels at the outermost edge of the organic electroluminescent display component. By carrying with the heat generated during the laser sintering process, the high-temperature resistant film can protect the pixel dots below the high-temperature resistant film so as to prevent the pixel dots from being burned and damaged by the heat generated by the laser.

For example, when the organic electroluminescent display component is encapsulated by an encapsulation cover, the frit usually is disposed at a periphery of the encapsulation cover. In the laser sintering process of the frit, the pixels that are easily burned and damaged by the heat of the laser are the ones at the outermost edge of the display component. Therefore, the high-temperature resistant film carrying with the heat of the laser is formed in a region corresponding to the pixels at the outermost edge of the display component so as to protect the pixels at the outermost edge of the display component. The frit may be formed on the encapsulation cover or on the base substrate as long as the encapsulation cover and the base substrate are bonded with each other. The high-temperature resistant film may be formed on an outer surface of the organic electroluminescent display component or on a surface of the encapsulation cover. Hereinafter, the two implementations of the high temperature film will be described in details with reference to the drawings.

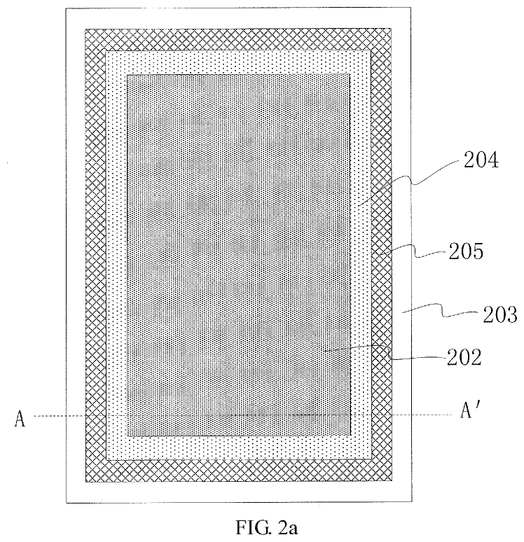

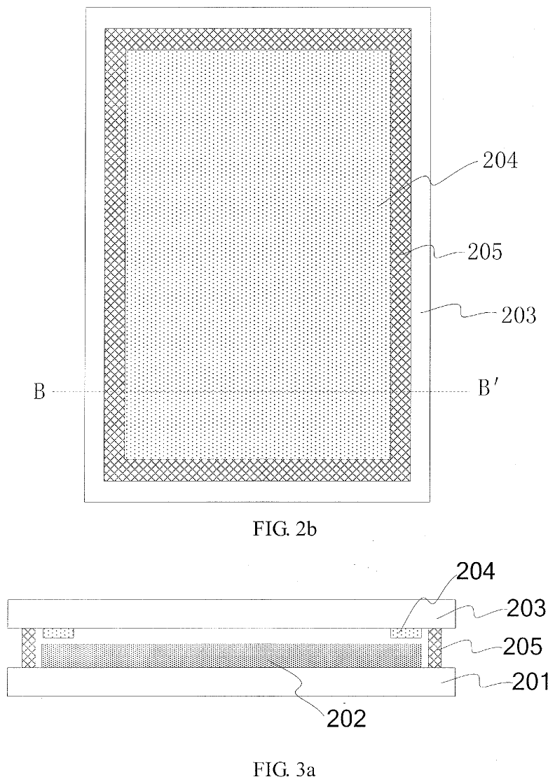

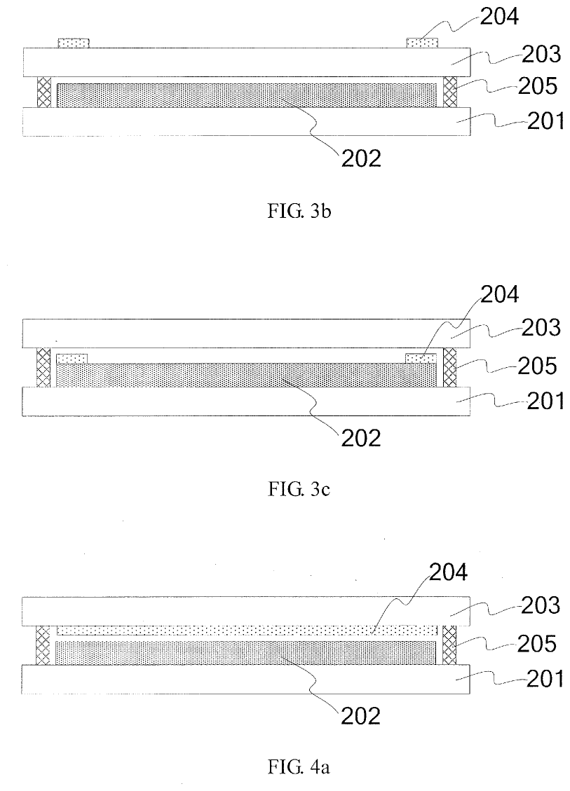

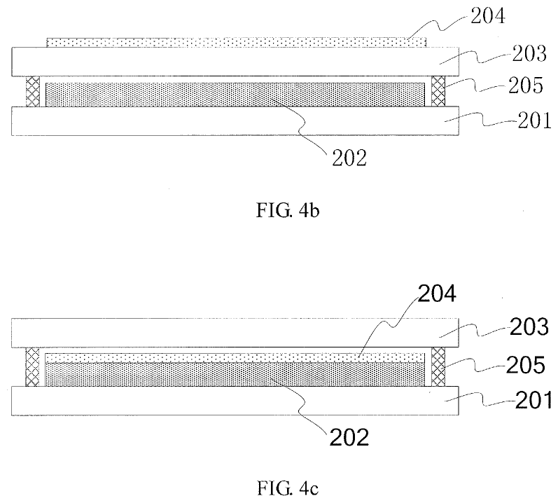

FIGS. 2a and 2b are top views of the organic electroluminescent display panel at a side where an encapsulation cover is located, in an embodiment of the present disclosure; FIGS. 3a, 3b and 3c are schematic cross-sectional views of a high-temperature resistant film located at different positions taken along line AA′ in FIG. 2a; and FIGS. 4a, 4b and 4c are schematic cross-sectional views of the high-temperature resistant film located at different positions taken along line BB′ in FIG. 2b.

A first implementation: the high-temperature resistant film is formed on the surface of the encapsulation cover;

In the above step S103, forming the frit on the encapsulation cover with the frit surrounding a region of the encapsulation cover corresponding to the pixels at the outermost edge of the organic electroluminescent display component may include:

as illustrated in FIG. 3a or 4a, on the encapsulation cover 203, a frit 205 is formed at a side where the high-temperature resistant film 204 is located, and the frit 205 surrounds a region of the encapsulation cover 203 corresponding to the pixels at the outermost edge of the organic electroluminescent display component 202; or

as illustrated in FIG. 3b or FIG. 4b, on the encapsulation cover 203, a frit 205 is formed at a side of the encapsulation cover facing away from the high-temperature resistant film 204, and the frit 205 surrounds a region of the encapsulation cover 203 corresponding to the pixels at the outermost edge of the organic electroluminescent display component 202.

For example, the high-temperature resistant film 204 may be formed by coating a high-temperature resistant material on the encapsulation cover 203, or may be formed by directly attaching a film layer having high-temperature resistant performance onto the encapsulation cover 203. The manner in which the high-temperature resistant film 204 is formed is not limited herein.

Referring to FIG. 3a or FIG. 4a, in the case where the high-temperature resistant film 204 and the frit 205 are formed at the same side of the encapsulation cover 203, because in the above step S105 the region of the encapsulation cover 203 where the frit 205 is located is sintered by using a laser after the encapsulation cover 203 is assembled with the organic electroluminescent display component 202 to form a cell, and because the high-temperature resistant film 204 is configured to protect the pixels during the laser sintering process, the high-temperature resistant film 204 is formed inside the cell. In order not to affect the display performance of the display device, the high-temperature resistant film 204 in the structure illustrated in FIG. 3a or FIG. 4a is made of a transparent material.

Referring to FIG. 3b or FIG. 4b, the frit 205 is formed at a side of the encapsulation cover facing away from the high-temperature resistant film 204.

In the above step S105, after sintering the region of the encapsulation cover 203 where the frit 205 is located by using a laser, the method further includes:

removing the high-temperature resistant film 204.

In the structure illustrated in FIG. 3b or FIG. 4b, the high-temperature resistant film 204 and the frit 205 are formed at different sides of the encapsulation cover 203. That is, the high-temperature resistant film 204 is formed on an external side of the cell formed by the encapsulation cover 203 and the organic electroluminescent display component 202. After the region of the encapsulation cover 203 where the frit 205 is located is sintered in step S105, the high-temperature resistant film 204 may be removed. For example, if the high-temperature resistant film 204 is formed by coating a high temperature resistant material on the encapsulation cover 203, then it may be removed by stripping after laser sintering; if the high-temperature resistant film 204 is directly attached onto the encapsulation cover 203, then it may be directly removed after laser sintering. Therefore, in the structure illustrated in FIG. 3b or FIG. 4b, no matter whether the high-temperature resistant film 204 is transparent or opaque, it does not affect the light transmittance of the display device.

Further, in the first implementation, in the above step S103, forming the high-temperature resistant film 204 may include:

forming a transparent high-temperature resistant film 204 at a region corresponding to the pixels at the outermost edge of the organic electroluminescent display component 202.

If the high-temperature resistant film 204 is made of a transparent material, no matter whether the high-temperature resistant film 204 is formed in the cell or outside the cell, it does not affect the display performance of the display device.

A second implementation: the high-temperature resistant film 204 is formed on the organic electroluminescent display component 202, as illustrated in FIG. 3c or 4c.

Forming the high-temperature resistant film 204 at the region corresponding to the pixels at the outermost edge of the organic electroluminescent display component 202 includes:

forming a transparent high-temperature resistant film 204 at a region corresponding to the pixels at the outermost edge of the organic electroluminescent display component 202.

Referring to FIG. 3c or 4c, the high-temperature resistant film 204 is formed on the organic electroluminescent display component 202 which is located on the base substrate 201. Because in the above step S105, the region of the encapsulation cover 203 where the frit 205 is located is sintered by using a laser after the encapsulation cover 203 is assembled with the organic electroluminescent display component 202 to form a cell, and because the high-temperature resistant film 204 is configured to protect the pixels during the laser sintering process, the high-temperature resistant film 204 is formed inside the cell. In order not to affect the display performance of the display device, the high-temperature resistant film 204 in the structure illustrated in FIG. 3c or FIG. 4c is made of a transparent material.

It should be explained that, referring to FIGS. 3a-3c and 4a-4c, the high-temperature resistant film 204 is formed on the region corresponding to the pixels at the outermost edge of the organic electroluminescent display component 202, and the frit 205 is formed at a periphery of the encapsulation cover 203, thus an interval with a certain width may be existed between the frit 205 and the region corresponding to the pixels at the outermost edge of the organic electroluminescent display component 202. Some metal wires may be disposed in the interval. That is, elements disposed at the interval usually are not burned or damaged by the heat of the laser. If the high-temperature resistant film 204 is further provided in a region corresponding to the interval, the display performance of the display device is still not affected. Therefore, the region corresponding to the interval may be provided with the high-temperature resistant film 204 or the high-temperature resistant film 204 may not be provided in the interval. For example, in order to simplify the manufacturing process and prevent the heat of the laser from entering the interval to damage the display device, the high-temperature resistant film 204 is usually disposed in close adjacent to the frit 205, i.e., the high-temperature resistant film 204 is also formed in the region corresponding to the interval.

For example, in the above manufacturing method provided by the embodiments of the present disclosure, in the step S103, forming the high-temperature resistant film 204 in the region corresponding to the pixels at the outermost edge of the organic electroluminescent display component 202 includes:

as illustrated in FIG. 2a, forming a high-temperature resistant film 204 in a region corresponding to pixels in a first layer to a third layer at the outermost edge of the organic electroluminescent display component 202; or

as illustrated in FIG. 2b, forming a high-temperature resistant film 204 in a region corresponding to all pixels of the organic electroluminescent display component 202.

Referring to FIG. 2a, in order to ensure that the high-temperature resistant film 204 can protect the display component from being burned and damaged, the high-temperature resistant film 204 corresponds to a region in which pixels of at least one layer at the outermost edge of the organic electroluminescent display component 202 are located, i.e., the high-temperature resistant film 204 has a width of about 1 mm. For example, the high-temperature resistant film 204 may be corresponding to a region in which pixels of a first layer to a third layer at the outermost edge of the organic electroluminescent display component 202 are located, i.e., the high-temperature resistant film 204 has a width of about 1-3 mm; or, referring to FIG. 2b, the high-temperature resistant film 204 may also be corresponding to a region in which all the pixels of the organic electroluminescent display component 202 are located. In the embodiments of the present disclosure, arranging the high-temperature resistant film 204 to be corresponding to a region in which pixels of a first layer to a third layer at the outermost edge of the organic electroluminescent display component 202 are located, and arranging the high-temperature resistant film 204 to be corresponding to a region in which all the pixels of the organic electroluminescent display component 202 are located, are merely two optional implementations of the present disclosure. For example, the high-temperature resistant film 204 may also be corresponding to a region in which pixels of other layer(s) at the outermost edge of the organic electroluminescent display component 202 are located, and the number of layer(s) of the pixels corresponding to the high temperature film 204 is not limited herein.

For example, in the above manufacturing method provided by the embodiments of the present disclosure, in the step S103, forming the high-temperature resistant film in the region corresponding to the pixels at the outermost edge of the organic electroluminescent display ILl component includes:

forming the high-temperature resistant film in the region corresponding to the pixels at the outermost edge of the organic electroluminescent display component by using polyethylene terephthalate (PET) or polyimide (PI).

For example, a solution of PET or PI may be coated in the region corresponding to the pixels at the outermost edge of the organic electroluminescent display component, and the coating layer can be heated and dried to form the high-temperature resistant film; or a high-temperature resistant film made of PET or PI may be directly attached onto the region corresponding to the pixels at the outermost edge of the organic electroluminescent display component. The high-temperature resistant film made of PET or PI is merely an optional implementation of the present disclosure, and other high temperature resistant materials may be used, without particularly limited herein.

For example, in the above manufacturing method provided by the embodiments of the present disclosure, in the step S103, forming the high-temperature resistant film in the region corresponding to the pixels at the outermost edge of the organic electroluminescent display component includes:

forming a high-temperature resistant film having a thickness of 100 Å to 500 Å in the region corresponding to the pixels at the outermost edge of the organic electroluminescent display component.

In order to ensure that the high-temperature resistant film can withstand the heat of laser sintering, the high-temperature resistant film has a thickness of at least 100 Å, for example, the thickness is ranging from 100 Å to 500 Å. The high-temperature resistant film having a thickness of 100 Å to 500 Å is merely an optional implementation of the embodiments of the present disclosure. In actual practice, the thickness of the high-temperature resistant film may be set as other values, and the thickness of the high temperature film is not limited herein.

Based on the same inventive concept, an embodiment of the present disclosure further provides an organic electroluminescence display panel, which is manufactured by the above manufacturing method. Because the principle of the organic electroluminescent display panel to solve the problem is similar to that of the above manufacturing method, the implementation of the organic electroluminescent display panel can be referred to the implementation of the above manufacturing method, and the repeated description will be omitted herein.

Based on the same inventive concept, an embodiment of the present disclosure further provides a display device including the above organic electroluminescent display panel. The display device can be applied to any product or component with a display function such as a mobile phone, a tablet computer, a television, a display, a notebook computer, a digital photo frame, and a navigator. Because the principle of the display device to solve the problem is similar to that of the above-mentioned organic electroluminescent display panel, the implementation of the display device can be referred to the implementation of the above-mentioned organic electroluminescent display panel, and the repeated description will be omitted herein.

In the above organic electroluminescent display panel, the manufacturing method thereof and the display device provided by the embodiments of the present disclosure, a high-temperature resistant film is formed on at least one of the organic electroluminescent display component and a surface of the encapsulation cover, in a region corresponding to pixels at an outermost edge of the organic electroluminescent display component. The high-temperature resistant film can withstand the heat generated during the laser sintering process and is configured to protect pixels below the high-temperature resistant film to prevent the heat generated by the laser from burning and damaging the pixels.

The above are merely exemplary embodiments of the present disclosure, and are not intended to limit the scope of the present disclosure. The scope of the present disclosure is defined by the appended claims.

The application claims priority to the Chinese patent application No. 201710333397.X, filed on May 12, 2017, the entire disclosure of which is incorporated herein by reference as part of the present application.

1. A manufacturing method of an organic electroluminescent display panel, comprising:
forming an organic electroluminescent display component on a base substrate;
providing an encapsulation cover;
forming a high-temperature resistant film on at least a partial region of at least one of a surface of the organic electroluminescent display component and a surface of the encapsulation cover with the at least a partial region corresponding to pixels at an outermost edge of the organic electroluminescent display component;
forming a frit on the encapsulation cover or the base substrate with the frit surrounding a region of the encapsulation cover or the base substrate corresponding to the pixels at the outermost edge of the organic electroluminescent display component; and
assembling the encapsulation cover with the organic electroluminescent display component to form a cell, and then sintering a region of the encapsulation cover corresponding to a region where the frit is located by using a laser.

2. The manufacturing method according to claim 1, wherein the high-temperature resistant film is formed on the surface of the encapsulation cover;
forming a frit on the encapsulation cover or the base substrate with the frit surrounding a region of the encapsulation cover or the base substrate corresponding to the pixels at the outermost edge of the organic electroluminescent display component comprises:
forming the frit on the encapsulation cover, at a side of the encapsulation cover where the high-temperature resistant film is located.

3. The manufacturing method according to claim 1, wherein the high-temperature resistant film is formed on the surface of the encapsulation cover;
forming a frit on the encapsulation cover or the base substrate with the frit surrounding a region of the encapsulation cover or the base substrate corresponding to the pixels at the outermost edge of the organic electroluminescent display component comprises:
forming the frit on the encapsulation cover, at a side of the encapsulation cover facing away from the high-temperature resistant film.

4. The manufacturing method according to claim 3, after sintering the region of the encapsulation cover corresponding to the region where the frit is located by using a laser, further comprising:
removing the high-temperature resistant film.

5. The manufacturing method according to claim 2, wherein the high-temperature resistant film is a transparent high-temperature resistant film.

6. The manufacturing method according to claim 1, wherein the high-temperature resistant film is formed on the surface of the organic electroluminescent display component;
forming a high-temperature resistant film on at least a partial region of at least one of a surface of the organic electroluminescent display component and a surface of the encapsulation cover with the at least a partial region corresponding to pixels at an outermost edge of the organic electroluminescent display component comprises:
forming a transparent high-temperature resistant film on a region corresponding to the pixels at the outermost edge of the organic electroluminescent display component.

7. The manufacturing method according to claim 1, wherein forming a high-temperature resistant film on at least a partial region of at least one of a surface of the organic electroluminescent display component and a surface of the encapsulation cover comprises:
forming a high-temperature resistant film on a region corresponding to pixels in a first layer to a third layer at the outermost edge of the organic electroluminescent display component.

8. The manufacturing method according to claim 1, wherein forming a high-temperature resistant film on at least a partial region of at least one of a surface of the organic electroluminescent display component and a surface of the encapsulation cover comprises:
forming a high-temperature resistant film on a region corresponding to all pixels of the organic electroluminescent display component.

9. The manufacturing method according to claim 1, wherein the high-temperature resistant film is made of polyethylene terephthalate or polyimide.

10. The manufacturing method according to claim 1, wherein the high-temperature resistant film has a thickness ranging from 100 Å to 500 Å.

11. An organic electroluminescence display panel manufactured by the manufacturing method according to claim 1.

12. A display device comprising the organic electroluminescent display panel according to claim 11.

13. The manufacturing method according to claim 3, wherein the high-temperature resistant film is a transparent high-temperature resistant film.

14. The manufacturing method according to claim 2, wherein forming a high-temperature resistant film on at least a partial region of at least one of a surface of the organic electroluminescent display component and a surface of the encapsulation cover comprises:
forming a high-temperature resistant film on a region corresponding to pixels in a first layer to a third layer at the outermost edge of the organic electroluminescent display component.

15. The manufacturing method according to claim 3, wherein forming a high-temperature resistant film on at least a partial region of at least one of a surface of the organic electroluminescent display component and a surface of the encapsulation cover comprises:
forming a high-temperature resistant film on a region corresponding to pixels in a first layer to a third layer at the outermost edge of the organic electroluminescent display component.

16. The manufacturing method according to claim 2, wherein forming a high-temperature resistant film on at least a partial region of at least one of a surface of the organic electroluminescent display component and a surface of the encapsulation cover comprises:
forming a high-temperature resistant film on a region corresponding to all pixels of the organic electroluminescent display component.

17. The manufacturing method according to claim 3, wherein forming a high-temperature resistant film on at least a partial region of at least one of a surface of the organic electroluminescent display component and a surface of the encapsulation cover comprises:
forming a high-temperature resistant film on a region corresponding to all pixels of the organic electroluminescent display component.

18. The manufacturing method according to claim 2, wherein the high-temperature resistant film is made of polyethylene terephthalate or polyimide.

19. The manufacturing method according to claim 3, wherein the high-temperature resistant film is made of polyethylene terephthalate or polyimide.
